(19) United States
(12) Patent Application Publication
(10) Pub. No.: US 2025/0393138 A1
(43) Pub. Date: Dec. 25, 2025

(54) RIGHT ANGLED CABLE CONNECTION FOR AUTOMOTIVE CAMERAS

(71) Applicant: Amphenol Corporation, WALLINGFORD, CT (US)

(72) Inventors: Joachim Grek, Wallingford, CT (US); Owen R. Barthelmes, Putnam Valley, NY (US); Michael Hoyack, Wallingford, CT (US); Joshua Sproule, Los Angeles, CA (US)

(21) Appl. No.: 19/244,090

(22) Filed: Jun. 20, 2025

Related U.S. Application Data
(60) Provisional application No. 63/662,569, filed on Jun. 21, 2024.

(51) Int. Cl. H05K 5/00; H01R 12/72; H04N 23/51; H04N 23/57

(52) U.S. Cl. CPC H05K 5/006; H01R 12/724; H04N 23/51; H04N 23/57; H05K 5/0052

(57) ABSTRACT

Automotive camera assemblies include a camera back housing configured to receive a printed circuit board (PCB) having a right-angled PCB connector defining a right-angle connection with the PCB, and the camera back housing includes a back wall and at least one sidewall with an internal cavity defined therein. An interface receptacle is defined on the at least one sidewall and a connector interface assembly is configured to be installed to the interface receptacle, the connector interface assembly configured to define a cable connection on the at least one sidewall of the camera back housing.

### CROSS-REFERENCE TO RELATED APPLICATIONS

This application claims the benefit of U.S. Provisional Patent Application No. 63/662,569, filed Jun. 21, 2024, the disclosure of which is incorporated herein by reference in its entirety.

### BACKGROUND

The subject matter disclosed herein generally relates to automotive cameras and, more particularly, to housings and connectors for automotive cameras.

Automotive cameras have become increasingly prevalent in modern vehicles, driven by the demand for advanced driver assistance systems (ADAS) and autonomous driving features. These cameras are integral to enabling functionalities such as lane departure warnings, adaptive cruise control, parking assistance, and object detection. As vehicles incorporate more cameras, the need for compact, reliable, and high-performance camera designs has grown significantly.

### SUMMARY

According to some embodiments, automotive camera assemblies are provided. The automotive camera assemblies include a camera back housing configured to receive a printed circuit board (PCB) having a right-angled PCB connector defining a right-angle connection with the PCB, wherein the camera back housing comprises a back wall and at least one sidewall and an internal cavity therein, an interface receptacle defined on the at least one sidewall, and a connector interface assembly configured to be installed to the interface receptacle, the connector interface assembly configured to define a cable connection on the at least one sidewall of the camera back housing.

In addition to one or more of the features described herein, or as an alternative, further embodiments of the automotive camera assemblies may include that the interface receptacle defines a connector aperture providing a through hole through the respective at least one sidewall from an external environment to the internal cavity.

In addition to one or more of the features described herein, or as an alternative, further embodiments of the automotive camera assemblies may include that the connector interface assembly includes a connector for electrical and mechanical engagement with the right-angled PCB connector at a first end of the connector and connection with a cable at a second end of the connector and an interface body housing the connector.

In addition to one or more of the features described herein, or as an alternative, further embodiments of the automotive camera assemblies may include that the interface body is fixedly connected to the camera back housing.

In addition to one or more of the features described herein, or as an alternative, further embodiments of the automotive camera assemblies may include that a portion of the interface receptacle is compressed about a portion of the interface body.

In addition to one or more of the features described herein, or as an alternative, further embodiments of the automotive camera assemblies may include that the connector is an adjustable connector configured to be adjustable within the interface body relative to an interface axis.

In addition to one or more of the features described herein, or as an alternative, further embodiments of the automotive camera assemblies may include a printed circuit board (PCB) having a right-angled PCB connector arranged within the internal cavity.

In addition to one or more of the features described herein, or as an alternative, further embodiments of the automotive camera assemblies may include a camera front assembly coupled to the camera back housing, the camera front assembly comprising a PCB having a right-angled PCB connector.

In addition to one or more of the features described herein, or as an alternative, further embodiments of the automotive camera assemblies may include that the camera front assembly includes a camera front housing, a charge-coupled device (CCD) imaging sensor, and an optical lens.

In addition to one or more of the features described herein, or as an alternative, further embodiments of the automotive camera assemblies may include that the camera front housing and the camera back housing are sealingly joined together.

In addition to one or more of the features described herein, or as an alternative, further embodiments of the automotive camera assemblies may include a cable electrically and mechanically coupled to the connector interface assembly.

In addition to one or more of the features described herein, or as an alternative, further embodiments of the automotive camera assemblies may include that the connector interface assembly comprises an adjustable connector configured to connect with the right-angled PCB connector at a first end and configured to connect with the cable at a second end, wherein the adjustable connector is movable within the connector interface assembly relative to an interface axis to accommodate an offset angle of the PCB connector.

In addition to one or more of the features described herein, or as an alternative, further embodiments of the automotive camera assemblies may include that the cable comprises a cable inner conductor, a cable dielectric, a shielding element, and a cable jacket. The connector interface assembly includes a connector sub-assembly configured to interface with the cable inner conductor, the cable dielectric, the shielding element, and the cable jacket to form a direct direction from the cable to the right-angled PCB connector.

In addition to one or more of the features described herein, or as an alternative, further embodiments of the automotive camera assemblies may include that the connector interface assembly comprises a snap body configured to engage with at least one of the interface receptacle and the at least one sidewall.

According to some embodiments, methods of assembling automotive camera assemblies are provided. The methods include arranging a printed circuit board (PCB) having a right-angled PCB connector within a camera back housing, wherein the camera back housing comprises at least one sidewall and a back wall and wherein the at least one sidewall comprises an interface receptacle and coupling a connector interface assembly to the interface receptacle, the connector interface assembly configured to define a cable connection on the at least one sidewall of the camera back housing.

In addition to one or more of the features described herein, or as an alternative, further embodiments of the methods may include that the interface receptacle defines a connector aperture providing a through hole through the respective at least one sidewall from an external environment to an internal cavity of the camera back housing.

In addition to one or more of the features described herein, or as an alternative, further embodiments of the methods may include that the PCB is part of a camera front assembly, wherein the method includes fixedly connecting the camera front assembly to the camera back housing to form an intermediate assembly with the PCB arranged within the internal cavity and the PCB connector arranged proximate the connector aperture.

In addition to one or more of the features described herein, or as an alternative, further embodiments of the methods may include pressure testing the intermediate assembly prior to coupling the connector interface assembly to the interface receptacle.

In addition to one or more of the features described herein, or as an alternative, further embodiments of the methods may include that the camera front assembly comprises a camera front housing, wherein the fixedly connecting comprises laser welding the camera front housing to the camera back housing.

In addition to one or more of the features described herein, or as an alternative, further embodiments of the methods may include electrically and mechanically coupling a cable to the connector interface assembly after coupling the connector interface assembly to the interface receptacle.

In addition to one or more of the features described herein, or as an alternative, further embodiments of the methods may include electrically and mechanically coupling a cable to the connector interface assembly before coupling the connector interface assembly to the interface receptacle.

In addition to one or more of the features described herein, or as an alternative, further embodiments of the methods may include that the connector interface assembly is configured to snap engage with the interface receptacle.

The foregoing features and elements may be combined in various combinations without exclusivity, unless expressly indicated otherwise. These features and elements as well as the operation thereof will become more apparent in light of the following description and the accompanying drawings. It should be understood, however, that the following description and drawings are intended to be illustrative and explanatory in nature and non-limiting.

### BRIEF DESCRIPTION OF THE DRAWINGS

The subject matter is particularly pointed out and distinctly claimed at the conclusion of the specification. The foregoing and other features, and advantages of the present disclosure are apparent from the following detailed description taken in conjunction with the accompanying drawings in which:

FIG. 1 is a schematic illustration of a conventional camera front assembly of an automotive camera assembly;

FIG. 2 is a schematic illustration of a conventional camera back assembly of an automotive camera assembly;

FIG. 3 is a schematic illustration of the camera front assembly of FIG. 1 assembled to the camera back assembly of FIG. 2;

FIG. 4 is a schematic illustration of the degrees of freedom and adjustment of components of the camera assembly of FIG. 3;

FIG. 5 is a schematic illustration of a camera front assembly of an automotive camera assembly having a right-angled printed circuit board connector configuration in accordance with an embodiment of the present disclosure;

FIG. 6 is a schematic illustration of a camera back assembly of an automotive camera assembly in accordance with an embodiment of the present disclosure;

FIG. 7 is a schematic illustration of an intermediate assembly of the camera front assembly of FIG. 5 assembled to the camera back assembly of FIG. 6 in accordance with an embodiment of the present disclosure;

FIG. 8 is a schematic illustration of a connector interface assembly for installation with to the camera back assembly in accordance with an embodiment of the present disclosure;

FIG. 9 is a schematic illustration of an installation step of installing the connector interface assembly of FIG. 8 to the intermediate assembly of FIG. 7;

FIG. 10 is a schematic illustration of an automotive camera assembly having a right-angled printed circuit board connector configuration in accordance with an embodiment of the present disclosure;

FIG. 11 is a schematic illustration of a portion of an automotive camera assembly in accordance with another embodiment of the present disclosure;

FIG. 12 is a schematic illustration of a portion of an automotive camera assembly in accordance with another embodiment of the present disclosure; and

FIG. 13 is a flow process for assembling an automotive camera assembly in accordance with an embodiment of the present disclosure.

### DETAILED DESCRIPTION

As shown and described herein, various features of the disclosure will be presented. A more thorough description will now be provided with reference to the accompanying figures. The details shown in the figures are not necessarily to scale, but are shown to aid in understanding the features of the subject technology.

Automotive cameras feature a housing that integrates an RF connector interface on the rear side of the camera. This design allows the camera to transmit video signals over coaxial RF transmission lines to other vehicle systems. However, the housing must meet stringent requirements for environmental sealing, radio frequency interference (RFI) shielding, and mechanical durability to ensure reliable operation in harsh automotive environments. The housing is often constructed from aluminum and laser welded to achieve water resistance and prevent degradation of sensitive electronic components, such as Serializer/Deserializer (SerDes) chips, which encode video signals.

Automotive camera housing designs face challenges in meeting the demands of modern automotive manufacturing processes. The integration of RF connectors into the housing complicates assembly workflows. Additionally, the presence of connectors can interfere with automated assembly equipment and prevent critical pressure testing of the laser welds after assembly. These limitations hinder the ability to optimize manufacturing efficiency and ensure the integrity of the camera housing.

Furthermore, the size and profile of camera housings have become limiting factors in vehicle integration. Automotive manufacturers increasingly require smaller camera packages to accommodate the compact spaces available in modern vehicle designs. Reducing the overall height and footprint of the camera housing is essential to meet these packaging constraints while maintaining performance standards.

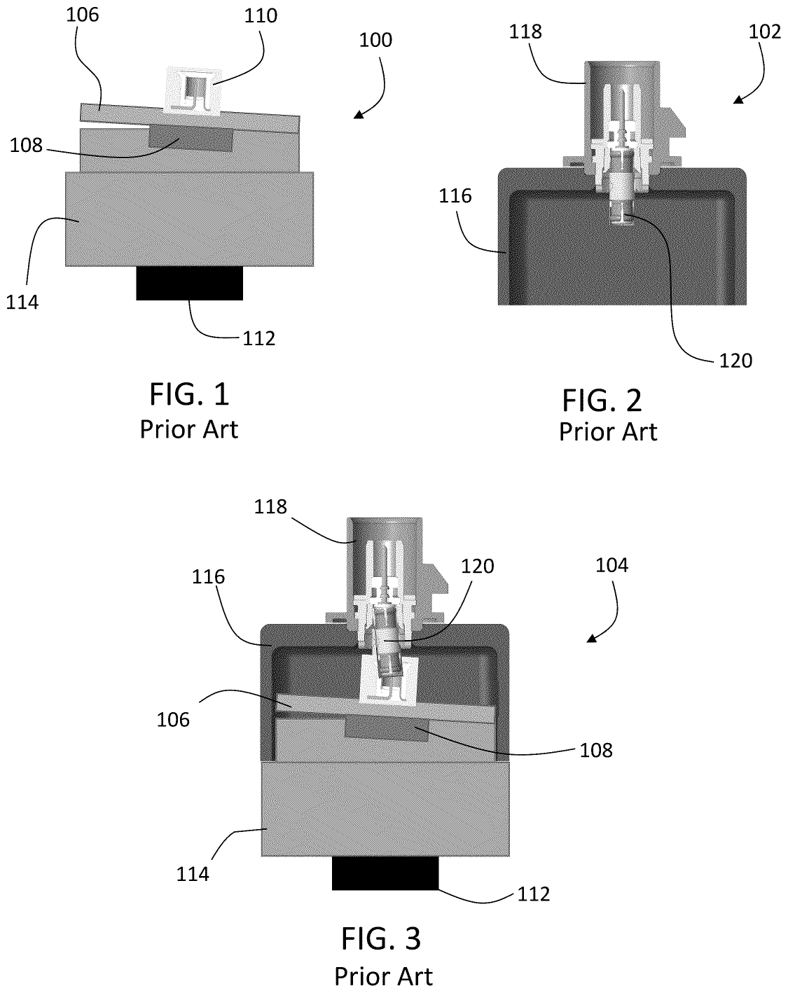

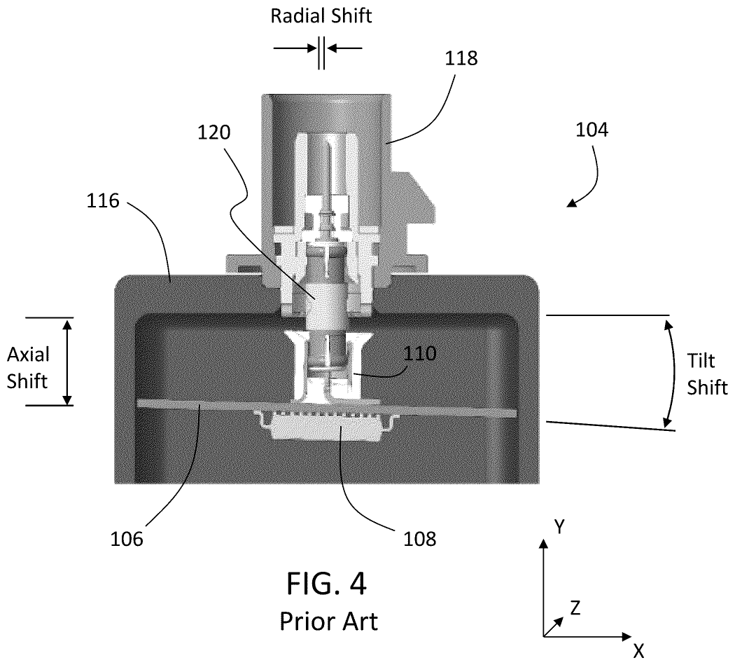

Referring to FIGS. 1-4, the components of a conventional camera manufacturing process are shown. FIG. 1 illustrates a camera front assembly 100, FIG. 2 illustrates a camera back assembly 102, and FIG. 3 illustrates the camera front assembly 100 assembled with the camera back assembly 102 to form a camera assembly 104. FIG. 4 illustrates the degrees of freedom and adjustment of components of the camera assembly 104.

The camera front assembly 100 includes a printed circuit board (PCB) 106, which may include a video Serializer/Deserializer (SerDes) chip (not shown) and a charge-coupled device (CCD) imaging sensor 108, a PCB connector 110, and an optical lens 112 assembled to a camera front housing 114. The CCD imaging sensor 108 is configured to capture images or data from the optical lens 112, which may be processed by the SerDes chip and/or other electronic components of the PCB 106. The PCB connector 110 provides for connection to a cable or cable connector for transmitting image and/or video data to other downstream systems, such as automotive processors or the like.

As shown in FIG. 2, the camera back assembly 102 is a separate structure to which the camera front assembly 100 is assembled to form the camera assembly 104. The camera back assembly 102 includes a camera back housing 116 and a cable connector 118. The cable connector 118 includes an adjustable connector 120 (e.g., bullet connector) that is mounted and arranged within the cable connector 118. The adjustable connector 120 is capable of pivoting or tilting within the cable connector 118 and is configured for electrical and mechanical engagement with the PCB connector 110, as shown in FIG. 3. During assembly, the CCD imaging sensor 108 may require relative adjustment (e.g., tilt, axial, and/or radial adjustment) relative to the optical lens 112. Because the CCD imaging sensor 108 is fixedly mounted on the PCB 106, the entire PCB 106 may be adjusted (e.g., tilt, axial, and/or radial adjustment) to ensure that the optics of the optical lens 112 are focused and aligned with the CCD imaging sensor 108.

Once the PCB 106 and CCD imaging sensor 108 are oriented relative to the optical lens 112, the camera front assembly 100 may be installed into the camera back assembly 102. During the installation, the adjustable connector 120 is inserted into and electrically engaged with the PCB connector 110. Because the PCB 106 may be tilted, axial adjusted, and/or radial adjusted to ensure optical performance, the adjustable connector 120 is also free to tilt, pivot, or otherwise accommodate the adjustment of the PCB 106, while ensuring necessary electrical connection and fidelity.

During installation of the PCB 106 to the camera front housing 114, for optical alignment of the CCD imaging sensor 108 with the optical lens 112, the PCB 106 may be adjusted about the X-Y-Z axes to focus the optical lens 112 to the CCD imaging sensor 108. Once the optimal position is achieved, the PCB 106 is fixed permanently in place to the camera front housing 114. The camera back housing 116 is integrated with an RF connector interface in the form of the cable connector 118 and adjustable connector 120. This adjustable connector 120, in this configuration, is a “bullet” RF interface that is designed to adapt to positional variations in the PCB connector 110 during assembly. The PCB connector 110 is integral with the PCB 106 and thus will be tiled or shifted when the CCD imaging sensor 108 is aligned with the optical lens 112. As shown in FIG. 4, the components of the camera front assembly 100 (e.g., PCB 106 and PCB connector 110) may be shifted axially, radially, and/or tilted with respect to the camera front housing 116 (axial being along a connection direction of the cable connector 110 with the adjustable connector 120). When the camera front assembly 100 and the camera back assembly 102 are joined together, the adjustable connector 120 may tilt or pivot as it engages with the cable connector 110, to accommodate any offsets or adjustments of the components of the camera front assembly 100. The camera assembly 104 is typically sealed using laser welding, although other methods such as threaded fasteners, adhesives, or ultrasonic welding may also be employed. Laser welding is preferred for its ability to achieve water resistance and ensure the integrity of the housing of the camera assembly 104.

The conventional manufacturing assembly has several limitations. For example, an attached cable, which connects to the cable connector 118, can interfere with automated assembly equipment, complicating the production process. Additionally, the presence of the cable can prevent pressure testing of laser welds after assembly is complete, which is critical for verifying the integrity of the housing. Another consideration is the size and volume that the camera assemblies occupy within the installation space within an automotive application. As shown in FIGS. 1-4, the cable connector 118 extends vertically from a top of the camera back housing 116. This results in a relatively large or tall profile, which can impact the ability for incorporating such cameras into automotive applications. These challenges highlight the need for improved manufacturing workflows that simplify assembly, enable automation, and allow for comprehensive testing of the environmental sealing of the housing.

Embodiments of the present disclosure are directed to a low-profile automotive camera assembly. In accordance with embodiments of the present disclosure a right-angle installation or connection is provided that results in a very low-profile camera assembly. That is, in accordance with embodiments of the present disclosure, a novel camera assembly construction is provided that changes the axis of assembly for the RF (cable) line into the camera housing. This design can be applied to both direct cable and connectorized solutions, offering a low-profile camera housing that is particularly advantageous for automotive applications with tight packaging constraints.

The camera assembly housings and configurations of the present disclosure utilize a right-angle PCB connector to steer the RF signal along an axis parallel to the orientation of the PCB, rather than vertically or perpendicular to the PCB, as shown in FIGS. 1-4. This design reduces the overall height of the camera housing and the height of the extension cable extending from the camera housing, enabling a lower-profile solution. The right-angle connection provided by embodiments of the present disclosure also provides improved manufacturing capabilities. For example, the cable or connector assembly for engagement with the PCB connector may be inserted into the housing cavity as a final assembly step, enabling automation and comprehensive testing of the environmental sealing of the housing and sealing elements prior to a cable or connector installation.

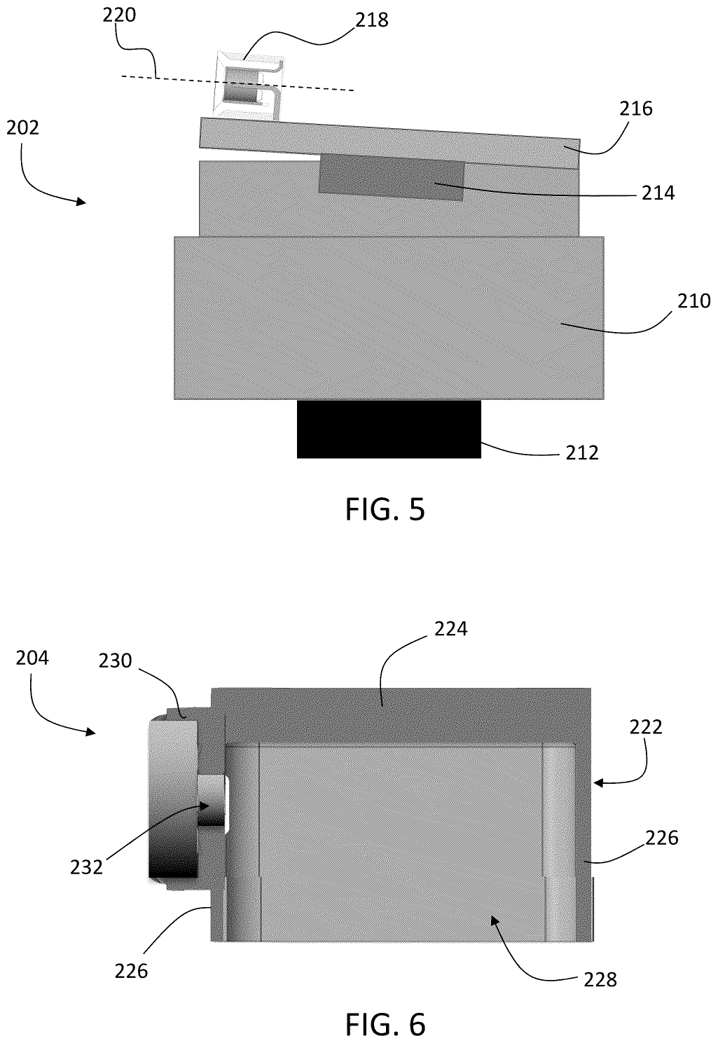

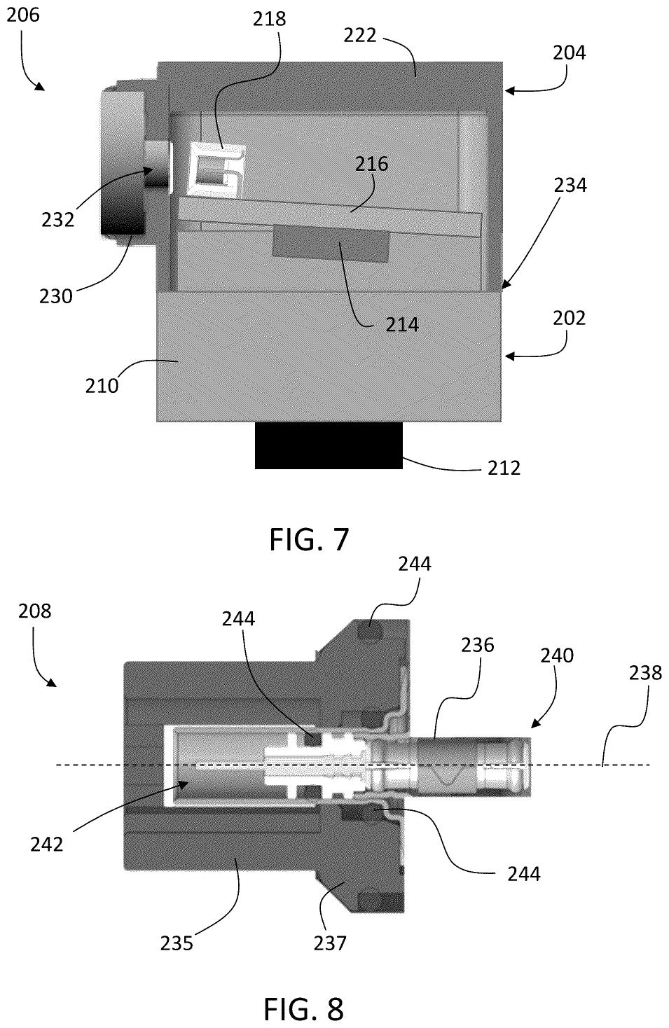

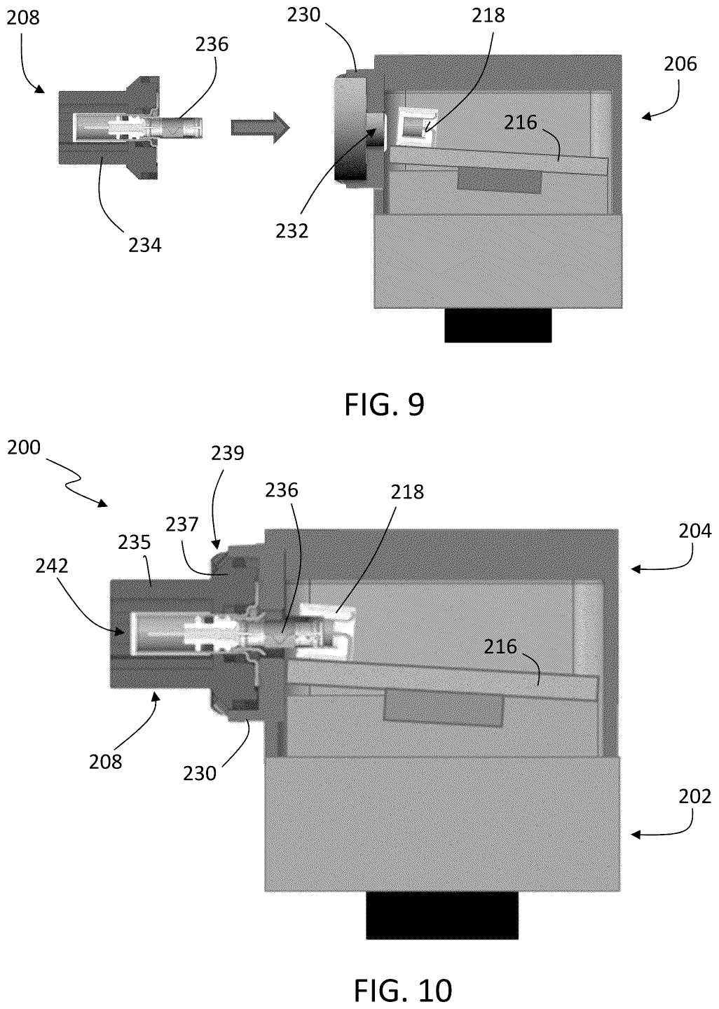

Referring now to FIGS. 5-10, schematic illustrations of an automotive camera assembly 200 in accordance with an embodiment of the present disclosure are shown. FIG. 5 illustrates a camera front assembly 202 and FIG. 6 illustrates a camera back assembly 204. FIG. 7 illustrates the camera front assembly 202 assembled to the camera back assembly 204 to form an intermediate assembly 206. FIG. 8 is a schematic illustration of a connector interface assembly 208 for installation to the intermediate assembly 206 and provides an interface connection for connecting a cable to the automotive camera assembly 200. FIG. 9 illustrates the installation of the connector interface assembly 208 to the intermediate assembly 206 and FIG. 10 illustrates the assembled automotive camera assembly 200.

The automotive camera assembly 200 is formed from the camera front assembly 202 assembled to the camera back assembly 204. The camera front assembly 202, as shown in FIG. 5, includes a camera front housing 210. The camera front housing 210 is configured to receive or otherwise house an optical lens 212 which is fixed to an exterior of the camera front housing 210. The optical lens 212 is fixed in position to the camera front housing 210 and a charge-coupled device (CCD) imaging sensor 214 is arranged to capture images or data from the optical lens 212. The CCD imaging sensor 214 is mounted on a printed circuit board (PCB) 216, which is mounted, attached, or affixed to the camera front housing 210. The PCB 216 includes a PCB connector 218. The PCB connector 218 is configured to electrically couple to a cable or the like for transmitting data from the PCB 216 (and associated components such as CCD imaging sensor 214) to another downstream component, such as a controller, onboard computer, general purpose computer, or the like, and/or to one or more displays, as will be appreciated by those of skill in the art. The camera front assembly 202 is configured to be installed to or assembled with the camera back assembly 204.

As shown in FIG. 5, the PCB connector 218 is arranged at an edge or end of the PCB 216. Furthermore, as illustrated, the PCB connector 218 has an orientation or axis of assembly 220 that is parallel with the PCB 216, rather than normal to the PCB (e.g., as shown in FIGS. 1-4). Because the axis of assembly 220 is parallel to the PCB 216, the PCB connector 218 is a right-angle connector that provides for a change in orientation from a connection inserted into the PCB connector 218 to the PCB 216.

Also shown in FIG. 5, is an offset installation of the PCB 216 to the camera front housing 210. As discussed above, the PCB 216 may be tilted, shifted, or otherwise adjusted in position and orientation relative to the camera front housing 210 during alignment of the optical lens 212 with the CCD imaging sensor 214. As illustrated, because of this offset or skew installation of the PCB 216 to the camera front housing 210, the axis of assembly 220 is tilted or angled relative to a level top of the camera front housing 210. This offset of angle may be compensated for via the other components of the automotive camera assembly 200, as described herein. The assembled camera front housing 210, with the optical lens 212, the CCD imaging sensor 214, the PCB 216, and the PCB connector 218 are configured for installation into and with the camera back assembly 204.

As shown in FIG. 6, the camera back assembly 204 includes a camera back housing 222. The camera back housing 222 includes a back wall 224 and one or more sidewalls 226. In a circular configuration, the camera back housing 222 may have a single, continuous sidewall 226, whereas in a squared or other polygonal-shaped housing may include two or more sidewalls 226. The sidewalls 226 extend perpendicular from the back wall 224. The back wall 224 and the sidewalls 226 define an internal cavity 228 that is sized to receive at least a portion of the camera front assembly 202. The camera back housing 222 is open at an end of the sidewalls 226 opposite the back wall 224. As shown in FIG. 6, the camera back housing 222 includes an interface receptacle 230. The interface receptacle 230 extends from the sidewall 226, such as one sidewall 226 of a plurality of sidewalls 226 of the camera back housing 222. The interface receptacle 230 defines a receiving structure for receiving the connector interface assembly 208 (FIG. 8). The interface receptacle 230 defines a connector aperture 232 that provides a through hole or opening for a part of the connector interface assembly 208 to pass through the sidewall 226 and engage with the PCB connector 218.

FIG. 7 illustrates the camera front assembly 202 assembled to the camera back assembly 204 to form the intermediate assembly 206. The camera back assembly 204 may be fixedly connected to the camera front assembly 202 along a housing interface 234. The housing interface 234 may be welded, ultrasonic welded, bonded, glued, or otherwise fixedly joined such that the camera back housing 222 is joined to the camera front housing 210. Mechanical joining, such as via threads on the housings 210, 22 and/or various fasteners (e.g., screws and associated brackets or plates), may be used. The housing interface 234 may be sealed, via the weld or other similar sealing mechanisms, including, but not limited to, seal elements (e.g., gaskets or the like). As noted above and as shown in FIG. 7, the PCB 216 is mounted or attached to the camera front housing 210 at an angle/skew, and thus the PCB connector 218 may be arranged at an angle or skew relative to the connector aperture 232. However, the camera front assembly 202 and the camera back assembly 204 are designed such that the installed PCB 216 will position the PCB connector 218 adjacent the connector aperture 232.

FIG. 8 illustrates the connector interface assembly 208. The connector interface assembly 208 is configured to provide a mechanism for connecting a cable to the PCB 216 through the PCB connector 218, thereby allowing for digital communication from the PCB 216 to another component through the connected cable. The connector interface assembly 208 includes an interface body 235 that houses an adjustable connector 236, such as a bullet connector of the like. The adjustable connector 236 is movable or adjustable within the interface body 235 relative to an interface axis 238 (e.g., tilt, angle, etc.) to accommodate offset of the PCB connector 218 (e.g., as shown in FIG. 7). A first end 240 of the adjustable connector 236 is configured for electrical and mechanical engagement and coupling with the PCB connector 218. A second end 242 of the adjustable connector 236 is configured for electrical and mechanical engagement and coupling with a cable (not shown). The connector interface assembly 208 includes one or more seal elements 244 to provide sealing within the connector interface assembly 208 and between the connector interface assembly 208 and the interface receptacle 230 of the camera back assembly 204.

FIG. 9 illustrates the assembly process of installing the connector interface assembly 208 to the intermediate assembly 206. During the installation process, the adjustable connector 236 of the connector interface assembly 208 is inserted into and through the connector aperture 232. The adjustable connector 236 may thus be inserted into and coupled to the PCB connector 218, thereby provide a mechanical and electrical connection from the PCB 216 to an attached cable. The first end 240 of the adjustable connector 236 is configured to engagement with the PCB connector 218. Once installed, a cable may be inserted into the connector interface assembly 208 such that a portion of the cable couples to the second end 242 of the adjustable connector 236. The connector interface assembly 208 may be fixed or attached to the camera back housing 222 within the interface receptacle 230 via welding, bonding, adhesives, snaps, clips, fasteners, threaded connection, or the like. In some configurations, material or edges of the interface receptacle 230 may be compressed or formed around the exterior of the interface body 235 to provide a fixed and secure connection.

With continued reference to FIGS. 5-10, an installation or assembly process will now be described. The camera front housing 210, including the PCB 216, the PCB connector 218, a video Serializer/Deserializer (SerDes) chip (not shown), the CCD imaging sensor 214, and the optical lens 212 are assembled to form the camera front assembly 202 (FIG. 5). During this assembly process, the PCB 216 is adjusted in the X-Y-Z axes to focus the optics of the optical lens 212 to the CCD imaging sensor 214. Once the optimal position is achieved, such as when a desired image capture quality is achieved, the PCB 216 is fixed permanently in place to the camera front housing 210.

Next, the camera front housing 210 is laser-welded to the camera back housing 222 of the camera back assembly 204 (FIG. 6) to form the intermediate assembly 206 (FIG. 7). At this stage, the intermediate assembly 206 can undergo pressure testing to verify the integrity of the laser weld between the housings 210, 222 and ensure water resistance. The intermediate assembly 206 can be tested and/or pressurized via the connector aperture 232, which can provide access to the interior of the intermediate assembly 206 prior to installation of the connector interface assembly 208.

Next, the connector interface assembly 208 (FIG. 8) may be inserted into the interface receptacle 230 and the adjustable connector 236 may pass through the connector aperture 232 to couple with the PCB connector 218 (FIGS. 9-10). The connector interface assembly 208 may be captured by parts of the interface receptacle 230 or otherwise securely and sealingly affixed to the interface receptacle 230. In some embodiments, sidewalls or edges of the interface receptacle 230 may be crimped or compressed about an exterior or base 237 of the interface body 235, as shown in FIG. 10 as a crimp region 239. In other embodiments, and/or in combination with a crimping, the base 237 of the interface body 235 may be welded, bonded, or otherwise attached to the interface receptacle 230. In some embodiments, a threaded connection, fasteners, or other mechanical engagement mechanisms may be employed without departing from the scope of the present disclosure.

The assembled automotive camera assembly 200 (FIG. 10) has a significantly lower profile or height as compared to convention automotive camera assemblies (e.g., FIGS. 1-4). The mounting and connection of a cable to a side of the automotive camera assembly 200 provides for unique installation processes and reduces the impact of the cameras within the spaces in which they are installed. As such, the very low-profile automotive camera assembly 200 of the present disclosure may provide various advantages over conventional automotive camera assemblies.

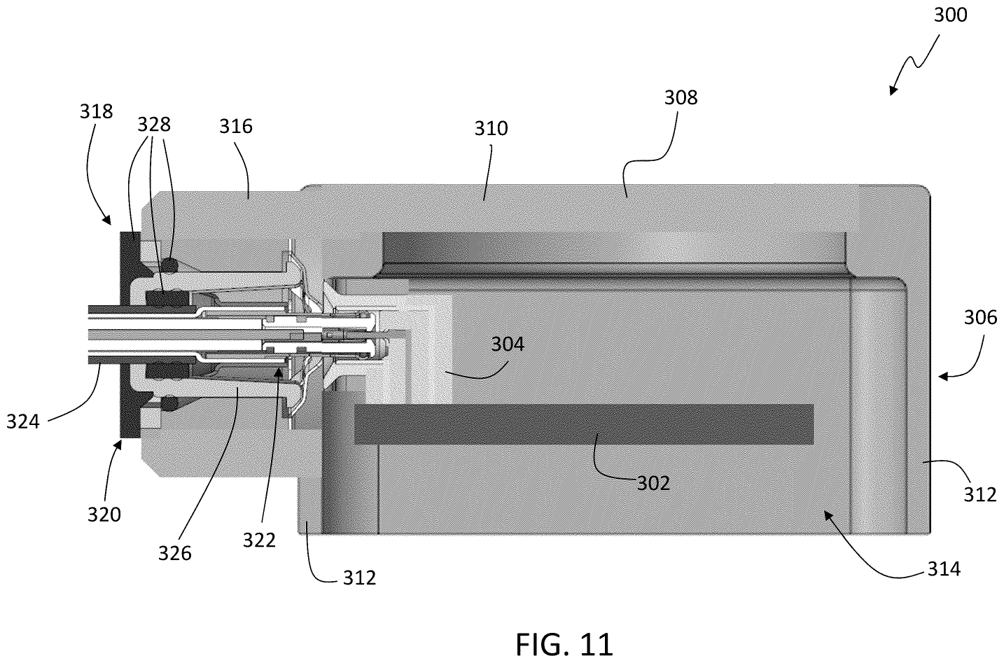

Referring now to FIG. 11, a schematic illustration of an automotive camera assembly 300 in accordance with another embodiment of the present disclosure is shown. The automotive camera assembly 300 may be similar to that shown and described above, and thus like features may be omitted in the illustrations and description. FIG. 11 illustrates portions of the automotive camera assembly 300, and omits the bulk of the camera front assembly (e.g., camera front housing and other components), and illustrates only a PCB 302 and a PCB connector 304 thereof. As shown and described above, the PCB 302 may be mounted or otherwise installed on a camera front housing and/or assembly, with the PCB 302 adjusted to ensure alignment of optics of the automotive camera assembly 300. The PCB 302 includes a right-angle PCB connector 304, similar to the right-angle PCB connector 218 of the automotive camera assembly 200.

As shown in FIG. 11, a camera back assembly 306 includes a camera back housing 308. The camera back housing 308 includes a back wall 310 and one or more sidewalls 312. The sidewalls 312 extend perpendicular from the back wall 310. The back wall 310 and the sidewalls 312 define an internal cavity 314 that is sized to receive at least a portion of the camera front assembly, such as the PCB 302 and associated components. The camera back housing 308 is open at an end of the sidewalls 312 opposite the back wall 310 and provides access to the internal cavity 314. As shown in FIG. 11, the camera back housing 308 includes an interface receptacle 316. The interface receptacle 316 extends from the sidewall 312, such as one sidewall 312 of a plurality of sidewalls 312 of the camera back housing 308. The interface receptacle 316 defines a receiving structure for receiving a connector interface assembly 318. The interface receptacle 316 defines a connector aperture that provides a through hole or opening for a part of the connector interface assembly 318 to pass through the sidewall 312 and engage with the PCB connector 304, similar to that shown and described above.

In this configuration, the interface receptacle 316 is configured to provide an interlocking feature for receiving and engaging with the connector interface assembly 318. The connector interface assembly 318 includes a direct connector assembly 320 that includes a connector sub-assembly 322 that is configured to interface with and electrically connect to the PCB 302 via the PCB connector 304 at one end/side and to a cable 324 at an opposite end/side. The direct connector assembly 320 includes a snap body 326 for mechanically engaging with the interface receptacle 316 and a set of sealing elements 328 for fluidly sealing the automotive camera assembly 300 at the connection point between the cable 324 and the interface receptacle 316. The snap body 326 is configured to engage with recesses or other features of the interface receptacle 316 and/or parts of the camera back housing 308. The snap body 326 is configured to provide a compressed engagement to provide a secure and sealed connection from the cable 324 to the PCB connector 304. The connector sub-assembly 322 provides a direct connection from the cable 324 to the PCB connector 304. The connector sub-assembly 322 may be configured to permit tilting or angling for engagement with a skewed PCB connector 304. In such embodiments, the tilting and adjustment may be provided at a pivot point at the connection between the connector sub-assembly 322 and the elements of the cable 324 (e.g., a cable inner conductor, a cable dielectric, a shielding element, and a cable jacket). The connector sub-assembly 322 may include connector contact, a connector insulator, and a connector body that are configured to be engaged with the components of the cable 324 and to provide mechanical and electrical connection from the cable 324 to the PCB connector 304.

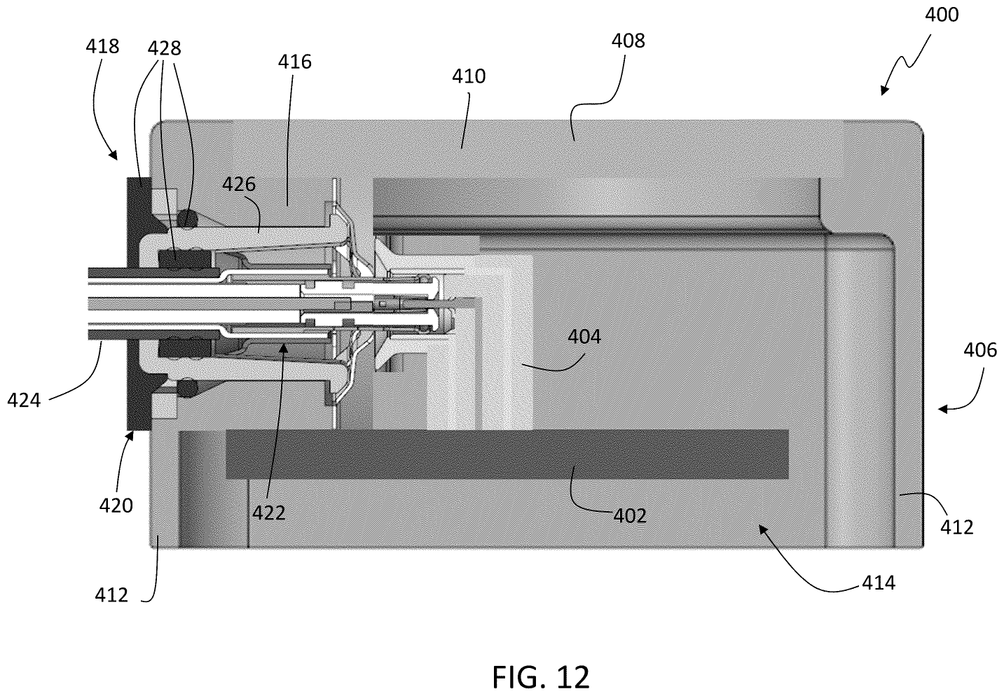

Referring now to FIG. 12, a schematic illustration of an automotive camera assembly 400 in accordance with another embodiment of the present disclosure is shown. The automotive camera assembly 400 may be similar to that shown and described above, and thus like features may be omitted in the illustrations and description. FIG. 12 illustrates portions of the automotive camera assembly 400, and omits the bulk of the camera front assembly (e.g., camera front housing and other components), and illustrates only a PCB 402 and a PCB connector 404 thereof. As shown and described above, the PCB 402 may be mounted or otherwise installed on a camera front housing and/or assembly, with the PCB 402 adjusted to ensure alignment of optics of the automotive camera assembly 400. The PCB 402 includes a right-angle PCB connector 404.

As shown in FIG. 12, a camera back assembly 406 includes a camera back housing 408 with a back wall 410 and one or more sidewalls 412, similar to that shown and described above. The camera back housing 408 defines an internal cavity 414. The camera back housing 408 includes an interface receptacle 416. The interface receptacle 416, in this embodiment, is arranged on/in one of the sidewalls 412, and extends into the internal cavity 414 of the camera back housing 408. The interface receptacle 416 defines a receiving structure for receiving a connector interface assembly 418. The interface receptacle 416 defines a connector aperture that provides a through hole or opening for a part of the connector interface assembly 418 to pass through the sidewall 412 and engage with the PCB connector 404, similar to that shown and described above. The interface receptacle 416 is configured to provide an interlocking feature for receiving and engaging with the connector interface assembly 418. The connector interface assembly 418 includes a direct connector assembly 420 that includes a connector sub-assembly 422 that is configured to interface with and electrically connect to the PCB 402 via the PCB connector 404 at one end/side and to a cable 424 at an opposite end/side. The direct connector assembly 420 includes a snap body 426 for mechanically engaging with the interface receptacle 416 and a set of sealing elements 428 for fluidly sealing the automotive camera assembly 400 at the connection point between the cable 424 and the interface receptacle 416.

In this configuration, as noted above, the interface receptacle 416 extends into the interior of the camera back housing 408. As such, the interface receptacle 416 occupies a portion of the internal cavity 414. Accordingly, the PCB connector 404 may be provided with a taller or longer vertical section before the right-hand turn, to accommodate the interface receptacle 416. In some configurations, and as shown in FIG. 12, the PCB 402 may abut the interface receptacle 416, although such aligned abutment may not be possible if the PCB 402 is skew due to optical alignment, and thus in other embodiments, a space or gap between the PCB 402 and the interface receptacle 416 may be provided to accommodate such skew.

In each of the embodiments of FIGS. 11-12, a direct cable solution is provided. That is, the cable may be directly coupled to the PCB connector via a connector sub-assembly. The connector sub-assembly is configured to directly interface with elements of the cable and provide electrical and mechanical connection to the PCB connector. In contrast, the embodiment of FIGS. 5-10 employs an intermediate adjustable connector that is arranged within an interface body. In each configuration, a cable is secured in place while maintaining environmental sealing, mechanical durability, RFI shielding, and signal integrity.

In the direct connection configurations (FIGS. 11-12), tilt and adjustment of connection with PCB connector is provided via bending or deflection of the cable itself, which is capable of adjustments at the interface with the connector sub-assembly. In contrast, in the intermediate configuration (FIGS. 5-10), the adjustable connector provides a tilt and adjustment to accommodate shifts/tilt/skew of the PCB connector.

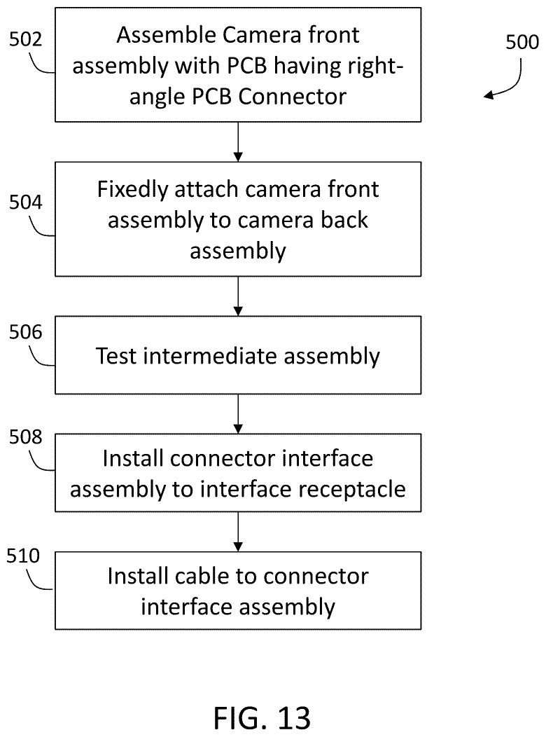

In accordance with embodiments of the present disclosure, an improved manufacturing process for automotive camera assemblies is provided. For example, with reference to FIG. 13, a flow process 500 for assembling an automotive camera assembly in accordance with an embodiment of the present disclosure is shown. Reference may be made to FIGS. 5-12 as examples of the structures and steps of the flow process 500, although it will be appreciated that the reference to such example embodiments is merely for illustrative and example purposes and the flow process 500 may be employed for manufacturing other configurations and arrangements of automotive camera assemblies without departing from the scope of the present disclosure.

At step 502 of flow process 500, a camara front assembly is assembled. The camera front assembly may include, without limitation, a camera front housing that houses an optical lens that is fixed in position to the camera front housing. The camera front assembly may also include a charge-coupled device (CCD) imaging sensor and a Serializer/Deserializer (SerDes) chip and other electronic components for receiving and processing image data received through the optical lens. The camera front assembly also includes a PCB upon which the electronic components may be mounted or otherwise integrated into. The PCB includes a right-angled PCB connector, which is configured for receiving or otherwise coupling to a cable for transmission of image data from the camera front assembly. During this assembly, the PCB may be angled or adjusted relative to the optical lens to ensure desired optical operation of the automotive camera assembly. Such adjustment may skew the PCB relative to the camera front housing, causing an axis of assembly that is skew relative to the rest of the camera front assembly (e.g., as shown in FIG. 5).

At step 504, the camera front assembly is fixedly attached to a camera back assembly. The camera back assembly includes a camera back housing. The camera back assembly includes an interface receptacle on a sidewall of the camera back housing. The interface receptacle includes or defines a connector aperture, such as shown in FIG. 6. During the assembly and attaching of the camera front assembly to the camera back assembly, the right-angled PCB connector of the camera front assembly is aligned with the connector aperture. The housing of the camera front assembly and the housing of the camera back assembly may be joined together. This joining may be achieved via welding, bonding, fastening, threaded connecting, or the like. The joining may be made such that an environmental seal is achieved such that a housing interface is fluidly sealed relative to an external environment. With the camera front assembly coupled with or joined to the camera back assembly, an intermediate assembly is formed.

At step 506, the intermediate assembly may be tested. The testing may be pressure testing of the joining of the camera front housing to the camera back housing, to ensure environmental sealing of the intermediate assembly. It is noted that during this testing step, the cable has not yet been installed to the camera assembly. A camera assembly is tested to ensure the joining method is complete, such as identifying any weld inconsistencies which can result in moisture migration into the camera. In some embodiments of the present disclosure, the camera assemblies may be tested with pressure the interface receptacles. In the case of a direct cable configuration, it may not be possible to pressurize the camera through the cable. To resolve this, in accordance with some embodiments of the present disclosure, the camera assemblies may be configured to provide access to the camera in the assembled state, for example after welding, so that the camera assembly can be pressurized and the moisture resistance can be confirmed.

At step 508, after the testing of the intermediate assembly is complete, a connector interface assembly is installed to the interface receptacle of the camera back housing. In some embodiments, the connector interface assembly may be mechanically connected to the interface receptacle via a crimping of material of the interface receptacle about a body of the connector interface assembly (e.g., FIG. 10). Additionally, or alternatively, the joining may be welds, bonding, adhesives, fasteners, threaded connections, or the like. In still further embodiments, the installation of the connector interface assembly may include a snap connection between a snap body of the connector interface assembly and a structure or feature of the interface receptacle and/or sidewall of the camera back housing. During this step, a portion of the connector interface assembly (e.g., direct connect assembly (e.g., FIGS. 11-12) or adjustable connector (e.g., FIGS. 8-10)) is electrically and mechanically connected to the PCB connector within the intermediate assembly (e.g., within the internal cavity of the assembled intermediate assembly).

At step 510, a cable may be connected to the connector interface assembly, completing the assembly of the automotive camera assembly. It will be appreciated that in certain configurations, such as those having a direct connect assembly (e.g., FIGS. 11-12), steps 508 and 510 may be a single assembly step. In such configurations, the direct connect assembly may be joined to the cable prior to installation into the interface receptacle, and thus the step of installing the direct connect assembly may also include the electrical and mechanical coupling with the PCB connector.

Embodiments of the present disclosure are directed to a right-angled connection for an automotive camera assembly. The right-angled connection configuration provides for a low-profile automotive camera. Such a construction can significantly reduce the vertical height of the camera housing, making it ideal for applications requiring compact designs. Furthermore, embodiments of the present disclosure enable enhanced manufacturing efficiency by allowing the cable or connector assembly to be installed as a final step. Advantageously, such a process becomes compatible with automated equipment and enables comprehensive testing of the housing prior to cable or connector installation. Advantageously, embodiments of the present disclosure provide for flexibility in integration. For example, the right-angle design can be adapted for both direct cable connection (e.g., FIGS. 11-12) and connectorized solutions (FIGS. 5-10), providing versatility for different automotive requirements.

The use of the terms “a”, “an”, “the”, and similar references in the context of description (especially in the context of the following claims) are to be construed to cover both the singular and the plural, unless otherwise indicated herein or specifically contradicted by context. The modifier “about” used in connection with a quantity is inclusive of the stated value and has the meaning dictated by the context (e.g., it includes the degree of error associated with measurement of the particular quantity). All ranges disclosed herein are inclusive of the endpoints, and the endpoints are independently combinable with each other. It should be appreciated that relative positional terms such as “forward,” “aft,” “upper,” “lower,” “above,” “below,” and the like are with reference to normal operational attitude and should not be considered otherwise limiting.

While the present disclosure has been described in detail in connection with only a limited number of embodiments, it should be readily understood that the present disclosure is not limited to such disclosed embodiments. Rather, the present disclosure can be modified to incorporate any number of variations, alterations, substitutions, combinations, sub-combinations, or equivalent arrangements not heretofore described, but which are commensurate with the scope of the present disclosure. Additionally, while various embodiments of the present disclosure have been described, it is to be understood that aspects of the present disclosure may include only some of the described embodiments. Accordingly, the present disclosure is not to be seen as limited by the foregoing description, but is only limited by the scope of the appended claims.

What is claimed is:

1. An automotive camera assembly comprising:
a camera back housing configured to receive a printed circuit board (PCB) having a right-angled PCB connector defining a right-angle connection with the PCB, wherein the camera back housing comprises a back wall and at least one sidewall and an internal cavity therein;
an interface receptacle defined on the at least one sidewall; and
a connector interface assembly configured to be installed to the interface receptacle, the connector interface assembly configured to define a cable connection on the at least one sidewall of the camera back housing.

2. The automotive camera assembly of claim 1, wherein the interface receptacle defines a connector aperture providing a through hole through the respective at least one sidewall from an external environment to the internal cavity.

3. The automotive camera assembly of claim 1, wherein the connector interface assembly comprises:
a connector for electrical and mechanical engagement with the right-angled PCB connector at a first end of the connector and connection with a cable at a second end of the connector; and
an interface body housing the connector.

4. The automotive camera assembly of claim 3, wherein the interface body is fixedly connected to the camera back housing.

5. The automotive camera assembly of claim 3, wherein a portion of the interface receptacle is compressed about a portion of the interface body.

6. The automative camera assembly of claim 3, wherein the connector is an adjustable connector configured to be adjustable within the interface body relative to an interface axis.

7. The automotive camera assembly of claim 1, further comprising a printed circuit board (PCB) having a right-angled PCB connector arranged within the internal cavity.

8. The automotive camera assembly of claim 1, further comprising a camera front assembly coupled to the camera back housing, the camera front assembly comprising a PCB having a right-angled PCB connector.

9. The automotive camera assembly of claim 8, wherein the camera front assembly comprises:
a camera front housing;
a charge-coupled device (CCD) imaging sensor; and
an optical lens.

10. The automotive camera assembly of claim 9, wherein the camera front housing and the camera back housing are sealingly joined together.

11. The automotive camera assembly of claim 1, further comprising a cable electrically and mechanically coupled to the connector interface assembly.

12. The automotive camera assembly of claim 11, wherein the connector interface assembly comprises an adjustable connector configured to connect with the right-angled PCB connector at a first end and configured to connect with the cable at a second end, wherein the adjustable connector is movable within the connector interface assembly relative to an interface axis to accommodate an offset angle of the PCB connector.

13. The automotive camera assembly of claim 11, wherein the cable comprises a cable inner conductor, a cable dielectric, a shielding element, and a cable jacket, wherein:
the connector interface assembly comprises a connector sub-assembly configured to interface with the cable inner conductor, the cable dielectric, the shielding element, and the cable jacket to form a direct direction from the cable to the right-angled PCB connector.

14. The automotive camera assembly of claim 1, wherein the connector interface assembly comprises a snap body configured to engage with at least one of the interface receptacle and the at least one sidewall.

15. A method of assembling an automotive camera assembly, the method comprising:
arranging a printed circuit board (PCB) having a right-angled PCB connector within a camera back housing, wherein the camera back housing comprises at least one sidewall and a back wall and wherein the at least one sidewall comprises an interface receptacle; and
coupling a connector interface assembly to the interface receptacle, the connector interface assembly configured to define a cable connection on the at least one sidewall of the camera back housing.

16. The method of claim 15, wherein the interface receptacle defines a connector aperture providing a through hole through the respective at least one sidewall from an external environment to an internal cavity of the camera back housing.

17. The method of claim 15, wherein the PCB is part of a camera front assembly, wherein the method further comprises:
fixedly connecting the camera front assembly to the camera back housing to form an intermediate assembly with the PCB arranged within the internal cavity and the PCB connector arranged proximate the connector aperture.

18. The method of claim 17, further comprising pressure testing the intermediate assembly prior to coupling the connector interface assembly to the interface receptacle.

19. The method of claim 17, wherein the camera front assembly comprises a camera front housing, wherein the fixedly connecting comprises laser welding the camera front housing to the camera back housing.

20. The method of claim 15, further comprising electrically and mechanically coupling a cable to the connector interface assembly after coupling the connector interface assembly to the interface receptacle.

21. The method of claim 15, further comprising electrically and mechanically coupling a cable to the connector interface assembly before coupling the connector interface assembly to the interface receptacle.

22. The method of claim 15, wherein the connector interface assembly is configured to snap engage with the interface receptacle.
